(19) United States
(12) Patent Application Publication
(10) Pub. No.: US 2002/0181525 A1
(43) Pub. Date: Dec. 5, 2002

(54) Semiconductor laser device

(75) Inventor: Akihiko Kasukawa, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC CO., LTD., Tokyo (JP)

(21) Appl. No.: 10/161,706

(22) Filed: Jun. 5, 2002

(30) Foreign Application Priority Data
Jun. 5, 2001 (JP) 2001-170146

(51) Int. Cl. H01S 5/00

(52) U.S. Cl. 372/43

(57) ABSTRACT

The semiconductor laser device comprises a laser-oscillating region, a wavelength-selecting region that has a chirped grating, a wavelength-variable region that converts a wavelength of a laser beam, and an amplification region that has a multiple quantum well structure formed of well layers each of a different thickness. These four regains are provided on the same substrate. A wavelength of the laser beam oscillated by the laser-oscillating region is selected by the wavelength-selecting region, and converted in the wavelength-variable region, The laser beam is amplified by the amplification region to be output from an emitting facet.

### FIELD OF THE INVENTION

This invention relates to a semiconductor laser device, which oscillates, amplifies, and emits, a laser beam that has two or more longitudinal modes of oscillation, which is suitable for a light source used in Raman amplification.

### BACKGROUND OF THE INVENTION

As the multimedia such as the Internet is becoming popular day by day, there is an increasing requirement to increase the capacity of the optical communication. It is known, that absorbance of light by an optical fiber is little for the bandwidths of 1310 nm or 1550 nm. Therefore, conventionally, one bandwidth from the above-mentioned bandwidths is generally employed in the optical communication. However, if a lot of information is to be transmitted, then the number of the optical fibers to be laid in a transmission path are required to be increased. Thus, conventionally, if the transmission capacity is to be increased, there is an inevitable increase in the costs.

The Wavelength Division Multiplexing (WDM) communication system, because it solves the above-mentioned problem, is being considered. The WDM communication system mainly employs an Erbium doped fiber amplifier (EDFA). Moreover, in the WDM communication system, transmission of data is performed using a plurality of wavelengths in the bandwidth of 1550 nm that is the operation range of the EDFA. Thus, in the WDM communication system, a plurality of light signals each with a different wavelength are transmitted simultaneously through a single optical fiber. Therefore, the transmission capacity of a network can be increased without increasing the number of the optical fibers in a transmission path.

The WDM communication system that uses the EDFA come into practical use first for the bandwidth of 1550 nm, because, gain flattening can be easily done for this bandwidth. Now a days, the bandwidth in which the WDM communication system has been used has been broadened to even a bandwidth of 1580 nm which was not used earlier for its small gain coefficient. However, a bandwidth for which the loss of intensity of light in an optical fiber is small is still broader than a bandwidth to which the EDFA can perform the amplification, Therefore, there is a rising interest in a light amplifier, i.e. a Raman amplifier, which functions even at a bandwidth which is not the bandwidth of the EDFA.

In the case of the Raman amplification, a powerful pump light is input through an optical fiber to pump the optical fiber. When a signal light having a wavelength in a range that is approximately 100 μm longer than the wavelength of the pump light, is input through the pumped optical fiber, there arises a gain in the range, thereby amplifying the signal light. As a result, the number of signal light channels in the WDM communication system using the Raman amplifier can be increased more than that in the communication system using the EDFA.

FIG. 7 shows the structure of a conventional laser device. This laser device emits a laser beam used as a pump light source for Raman amplification. The laser device comprises a semiconductor light-emitting diode 202 and an optical fiber 203. The semiconductor light-emitting diode 202 comprises an active layer 221. The active layer 221 is provided with a light-reflecting surface 222 on one end, and a light-emitting surface 223 on the other end. A light produced in the active layer 221 is reflected by the light-reflecting surface 222 to be output from the light-emitting surface 223.

An optical fiber 203 is placed at the light-emitting surface 223 of the semiconductor light-emitting diode 202 to be optically coupled with the light-emitting surface 223. In a core 232 inside the optical fiber 203 a fiber grating 233 is formed at a certain distance from the light-emitting surface 223. The fiber grating 233 selectively reflects a light of a particular wavelength. In other words, the fiber grating 233 functions as an external resonator, formed between the fiber grating 233 and the light-reflecting surface 222, and a laser beam of a particular wavelength selected by the fiber grating 233 is amplified to be output as an output laser beam 241.

A MOPA semiconductor laser device, using a distributed feedback (DFB) laser or a distributed Bragg reflector (DBR) laser as a laser beam source used as the pump light source for Raman amplification, and having a laser amplification region, has been used in some cases. The MOPA semiconductor laser device oscillates, amplifies and outputs the light stably in a single longitudinal mode, since the laser light-emitting diode in the MOPA semiconductor laser device is provided with a diffraction grating.

However, since the distance between the fiber grating 233 and the semiconductor light-emitting diode 202 is long in the above-described conventional laser device, a relative intensity noise (RIN) caused by a resonance between the fiber grating 233 and the light-reflecting surface 222 is increased. As a result, when the above-described conventional laser device is used for Raman amplification, a fluctuation in intensity of a pump light output from the laser device causes a fluctuation in Raman gain and the fluctuation in Raman gain is also amplified, to be output as a fluctuation in signal strength. Therefore, it is difficult to execute a stable Raman amplification with the conventional device.

In the above-described conventional laser device, it is required that the optical fiber 203 having the fiber grating 233 is optically coupled with the semiconductor light-emitting diode 202. Since this is a mechanical optical coupling within the resonator, oscillation properties of the laser may be changed due to a mechanical vibration or the like, and it is difficult to provide a stable pump light.

When the MOPA semiconductor laser device is used, since the laser beam is oscillated in a single longitudinal mode, it is difficult to pump the fiber at a high power. Moreover, when the laser beam having a single longitudinal mode is used, a threshold light intensity for a stimulated Brillouin scattering is exceeded during Raman amplification, causing a stimulated Brillouin scattering that results in an increase of noises.

Furthermore, in the above-described conventional laser device, it is required to provide a high-power laser and a fiber grating that are suitable for a wavelength range where Raman amplification is carried out and if Raman amplification is to be done at a different wavelength, a semiconductor laser device has to be provided separately for each wavelength.

### SUMMARY OF THE INVENTION

It is an object of the present invention to provide a semiconductor laser device, which is suitable for a light source used in Raman amplification, wherein a stable and high gain can be achieved.

The semiconductor laser device according to the present invention comprises: an oscillation unit which outputs a laser beam that has a plurality of longitudinal modes of oscillation; a wavelength converting unit which converts a wavelength of the laser beam that is oscillated by the oscillation unit; and a light-amplifying unit which amplifies the laser beam that is oscillated by the oscillation unit. The oscillation unit, the wavelength converting unit, and the light-amplifying unit are placed on the same semiconductor substrate.

Thus, the semiconductor laser device according to the present invention amplifies the laser beam that has a plurality of longitudinal modes of oscillation, changes its wavelength into a desired wavelength, and outputs the laser beam.

Other objects and features of this invention will become apparent from the following description with reference to the accompanying drawings.

### BRIEF DESCRIPTION OF THE DRAWINGS

FIG. 1 is a diagram showing a schematic structure of a semiconductor laser device according to a first embodiment of the invention.

FIG. 2 is a diagram showing a relationship between an oscillation wavelength spectrum of the semiconductor laser device shown in FIG. 1 and a longitudinal mode of oscillation.

FIG. 3 is a diagram showing a sectional view taken along a line A-A of a wavelength-selecting region shown in FIG. 1.

FIG. 4A is a diagram that shows a relationship between a laser beam output and a single longitudinal mode of oscillation; and a threshold value of a stimulated Brillouin scattering.

FIG. 4B is a diagram that shows a relationship between a laser beam output and a plurality of longitudinal modes of oscillation; and the threshold value of the stimulated Brillouin scattering.

FIG. 5 is a diagram showing a schematic structure of a semiconductor laser device according to a second embodiment of the invention.

FIG. 6 is a diagram showing a sectional view taken along a line B-B of a DFB laser region shown in FIG. 5.

FIG. 7 is a diagram showing a schematic structure of a conventional semiconductor laser device.

### DETAILED DESCRIPTION

Embodiments of a semiconductor laser device according to the present invention will now be explained in detail while referring to the accompanying drawings.

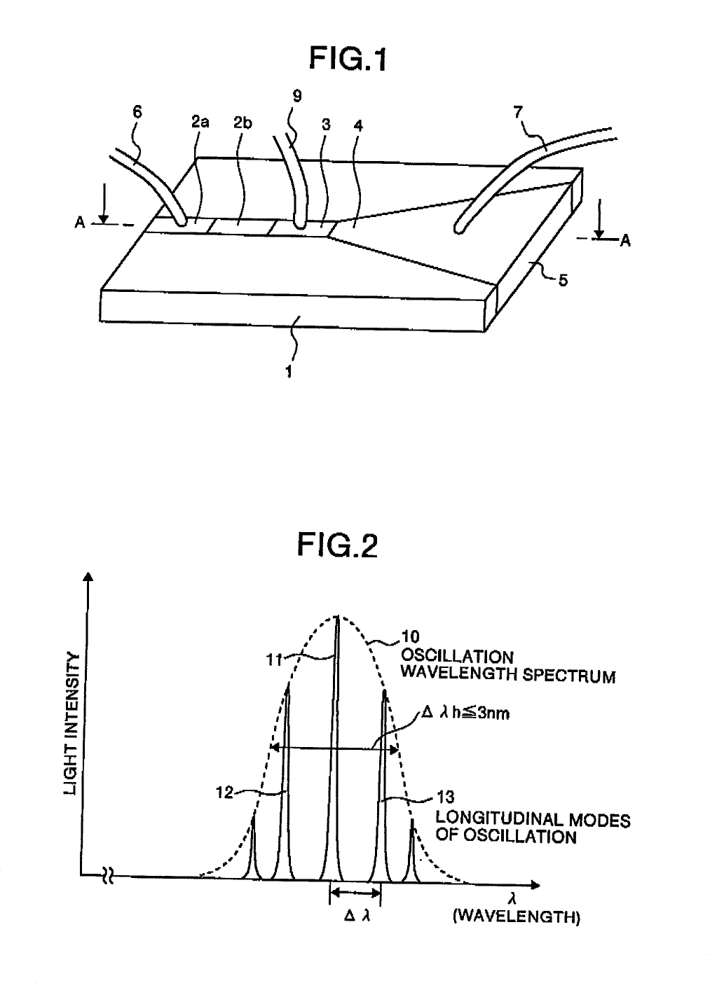

FIG. 1 shows a schematic structure of a semiconductor laser device according to a first embodiment of to the present invention. The semiconductor laser device 1 has, on the same semiconductor substrate, a laser-oscillating region 2a which oscillates a laser beam, a wavelength-selecting region 2b which has a diffraction grating 8, a wavelength-variable region 3 which converts a wavelength of the laser beam, and an amplification region 4 which amplifies the laser beam.

The laser-oscillating region 2a is connected with a power supply 6, and oscillates a laser beam. A longitudinal mode spacing Δλ of the laser beam oscillated by the laser-oscillating region 2a is determined by an oscillation wavelength, an equivalent refractive index, and a resonator length.

The wavelength-selecting region 2b selects a longitudinal mode according to the Bragg wavelength of the diffraction grating. A wavelength-selecting characteristic by the diffraction grating is shown by an oscillation wavelength spectrum 10 in FIG. 2. Longitudinal modes that exist within a half-width Δλh of the oscillation wavelength spectrum 10 are to be oscillated. The oscillation wavelength spectrum 10 is determined by the grating pitch of the diffraction grating.

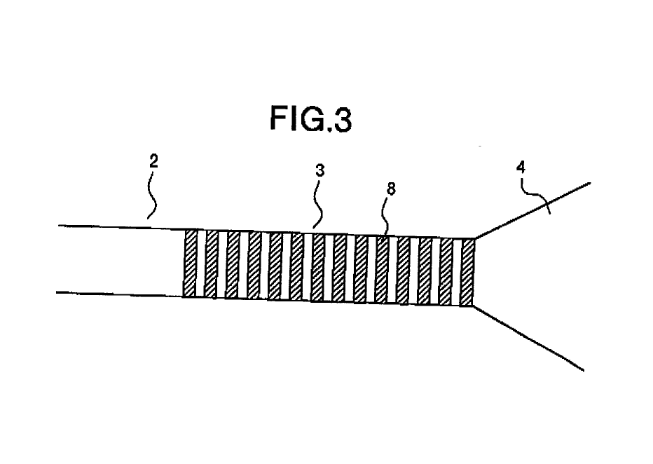

FIG. 3 shows a sectional view taken along the line A-A of the wavelength-selecting region 2B. The diffraction grating 8 is a chirped grating wherein the grating pitch changes periodically. The chirped grating causes a fluctuation in the wavelength-selecting characteristic such that a number of the longitudinal modes within the half-width Δλh of the oscillation wavelength spectrum 10 is to be plural. In FIG. 2, there are three longitudinal modes of oscillation 11, 12, and 13 within the half-width Δλh of the oscillation wavelength spectrum.

The wavelength-variable region 3 is connected with a power supply 9, and carries out a wavelength conversion. The wavelength-variable region 3 prevents a fluctuation in an output dependent on the wavelength of the laser beam by controlling the output of the laser beam oscillated in the wavelength conversion, to oscillate a laser beam having a uniform output.

The amplification region 4 is connected with a power supply 7, and amplifies the laser beam. Further, the amplification region 4 comprises a multiple quantum well structure formed of well layers each of a different thickness, and amplifies the laser beam having a plurality of longitudinal modes, efficiently. The amplified laser beam is output from an emitting facet 5. A gain of in the laser beam can be determined by controlling an amount of the electric current supplied by the power supply 7.

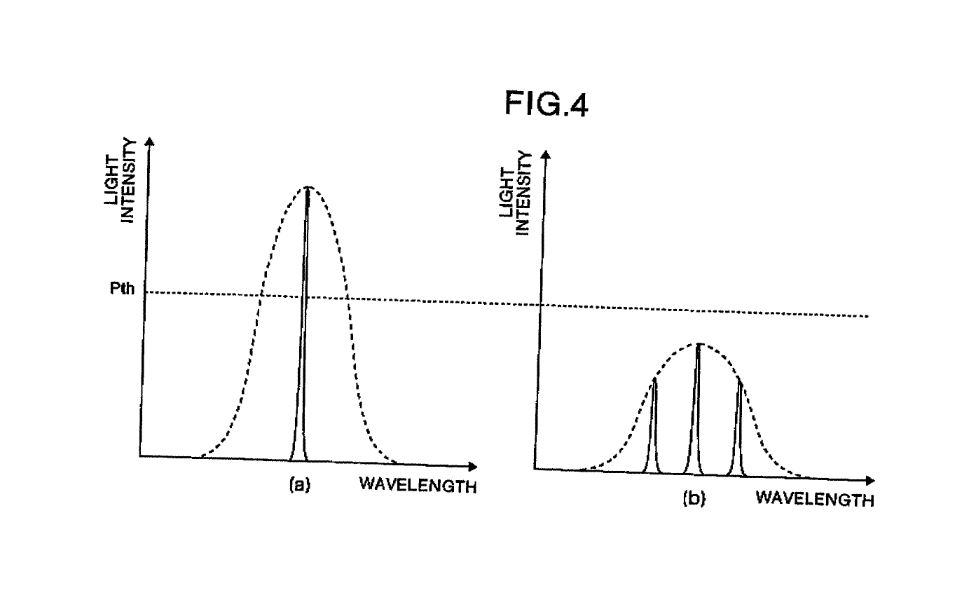

According to the semiconductor laser device of the first embodiment, a number of the longitudinal modes of oscillation of the laser beam can be set to a desired number by setting the grating pitch of the diffraction grating. In contrast to the case where a laser beam having a single longitudinal mode is used, when a laser beam having a plurality of longitudinal modes of oscillation is used, a high output value can be obtained while suppressing the peak value of the laser output. For example, the semiconductor laser device shown in the first embodiment has a profile shown in FIG. 4E, and can obtain a high laser output with a small peak value. In contrast, FIG. 4A shows a profile of a semiconductor laser device that oscillates a laser beam having a single longitudinal mode, when the same laser output as that in FIG. 4B is to be obtained; and the profile has a large peak value.

A light source for pumping used in a Raman amplifier preferably has a high output, however, if the peak value of a pump light is too large, a stimulated Brillouin scattering occurs, causing an increase in noises. The stimulated Brillouin scattering occurs when the output exceeds a threshold value Pth. To obtain a laser power equivalent to that in the case of FIG. 4A, a plurality of longitudinal modes of oscillation in the profile as shown in rig. 4B, is required, such that the peak value in the profile is decreased and a high output of pump light can be obtained under the threshold value Pth of the stimulated Brillouin scattering, thereby being able to obtain a large Raman gain.

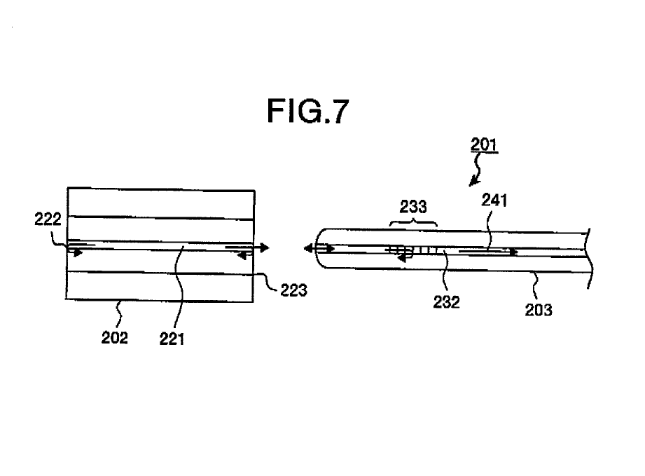

Since the conventional semiconductor laser device uses a semiconductor laser module having the fiber grating as shown in FIG. 7, the relative intensity noise (RIN) is increased under the influence of the resonance between the fiber grating 233 and the light-reflecting surface 222 such that constant Raman amplification cannot be achieved. On the other hand, the semiconductor laser device 1 shown in the first embodiment does not use the fiber grating 233, and the laser beam emitted by the device 1 can be directly used as a pump light source for a Raman amplifier, with a smaller RIN. As a result, a fluctuation of a Raman gain is reduced, and a stable Raman amplification can be carried out.

In the conventional semiconductor laser device shown in FIG. 7, the resonator requires a mechanical coupling. There occurs a variation in the oscillation characteristic of the laser due to a vibration or the like resulting from the mechanical coupling. In contrast, the semiconductor laser device according to the first embodiment has no variation in the oscillation characteristic, providing a stable optical output.

Moreover, in the semiconductor laser device according to the first embodiment, the laser-oscillating region and the amplification region are provided on the same semiconductor substrate. Therefore, the laser beam can be amplified to have a power required for Raman amplification before being output.

According to the first embodiment, in the semiconductor laser device 1, the laser-oscillating region 2a, the wavelength-selecting region 2b which has the chirped grating, the wavelength-variable region 3 which converts the wavelength of the laser beam, and the amplification region 4 which has the multiple quanta well structure formed of well layers each of a different thickness have been provided on the same semiconductor substrate. Therefore, in this semiconductor laser device 1, a high-power laser beam having a plurality of longitudinal modes can be output stably.

Moreover, when the semiconductor laser device 1 is used as a pump light source for Raman amplification, no stimulated Brillouin scattering is caused, and a stable and large Raman gain can be obtained.

In addition, although in the first embodiment, the number of longitudinal modes of oscillation of the laser beam is plural since the diffraction grating 8 is the chirped grating, the grating length of the diffraction grating, the resonator length, or the refractive index may be varied instead to provide the same effect. For example, a value of the normalized coupling coefficient κLg, i.e. the product of the diffraction-grating length Lg and the coupling coefficient κ, may be set as “2”, instead. In this cases also, the number of the longitudinal modes of oscillation can be increased and, a high-power laser beam having a plurality of longitudinal modes can be stably output just like when the diffraction grating is the chirped grating.

A second embodiment of the present invention will now be explained. In the first embodiment, the semiconductor laser device using the DBR laser is described, while in this second embodiment, a semiconductor laser device using a DFB laser will be described.

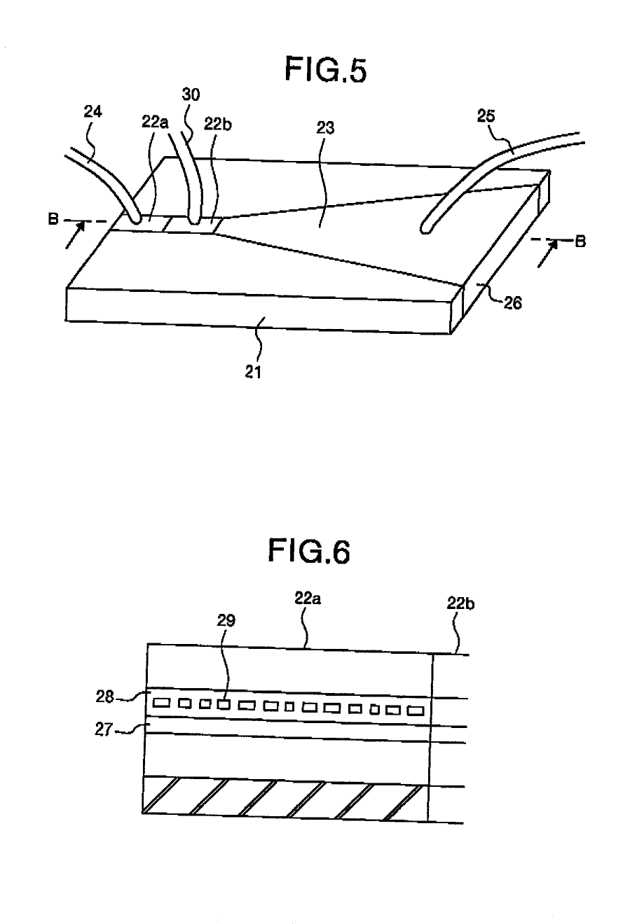

FIG. 5 shows a schematic structure of the laser device according to the second embodiment of the invention. The semiconductor laser device 21 has, on the same semiconductor substrate, a DFB laser region 22a which oscillates a laser beam, a wavelength-variable region 22b which converts a wavelength of the laser beam, and an amplification region 23 which amplifies the laser beam.

The DFB laser region 22a is connected with a power supply 24 and oscillates the laser beam. Further, the DFB laser region 22a comprises a diffraction grating 29 inside, to select a longitudinal mode according to the Bragg wavelength of the diffraction grating.

FIG. 6 shows a sectional view taken along the line B-B of the DFB laser region 22a. The diffraction grating 29 is embedded in a spacer layer 28 provided on top of an active layer 27. Further, the diffraction grating 29 is a chirped grating wherein a grating pitch varies periodically. The chirped grating causes a fluctuation in a wavelength-selecting characteristic of the diffraction grating such that a number of longitudinal modes within a half-width Δλh of an oscillation wavelength spectrum 10 becomes plural.

The wavelength-variable region 22b is connected with a power supply 30 and carries out a wavelength conversion. The wavelength-variable region 22b controls the power of the laser beam oscillated in the wavelength conversion, to prevent a fluctuation in an output dependent on the wavelength of the laser beam and to oscillate a laser beam having a uniform output.

The amplification region 23 is connected with a power supply 25, and amplifies the laser beam. Further, the amplification region 4 (Translator's comment: ‘4’ is a mistake of “23”) has a multiple quantum well structure formed of well layers each of a different thickness, and amplifies the laser beam having a plurality of longitudinal modes efficiently. The amplified laser beam is output from an emitting facet 26. A gain in the laser beam can be determined by controlling an amount of the electric current supplied by the power supply 25, According to the semiconductor laser device of the second embodiment, a number of the longitudinal modes of oscillation of the laser beam can be set to a desired number by setting the grating pitch of the diffraction grating.

According to the second embodiment, in the semiconductor laser device 21, the DFB laser region 22a, the wavelength-variable region 22b which converts the wavelength of the laser beam, and the amplification region 23 which has the multiple quantum well structure formed of well layers each of a different thickness have been provided on the same semiconductor substrate. Therefore, a high power laser beam having a plurality of longitudinal modes can be stably output.

Moreover, when the semiconductor laser device 21 is used as a pump light source for Raman amplification, no stimulated Brillouin scattering is caused, and a stable and large Raman gain can be obtained.

In addition, although in the second embodiment, the number of longitudinal modes of oscillation of the laser beam is plural since the diffraction grating is the chirped grating, the grating length of the diffraction grating, the resonator length, or the refractive index may be varied instead to provide the same effect. In this case also, the number of the longitudinal modes of oscillation can be increased such that a high-power laser beam having a plurality of longitudinal modes can be stably output just like when the diffraction grating is the chirped grating.

As explained above, the semiconductor laser device according to the present invention amplifies the laser beam that has a plurality of longitudinal modes of oscillation, changes its wavelength into a desired wavelength, and outputs the laser beam. As a result, a semiconductor laser device can be provided in which an adjustment of an optical axis is not required, a body of the device can be downsized and a constant and high-power laser beam can be emitted with its wavelength changed to a desired wavelength; which can be widely used even if the output laser beam is to go through Raman amplification carried out with a different wavelength. Further, a single model of the semiconductor laser device can be used over a wavelength range of about 100 nm. Moreover, there is no need to arrange a variety of laser diodes corresponding to a case when pump lasers having different wavelengths are multiplexed to obtain Raman effect. In other words, a Raman amplifier can be constructed with only one laser diode of the present invention.

Furthermore, the semiconductor laser device includes a plurality of longitudinal modes of oscillation, and amplifies the laser beam using the amplifying unit having the multiple quantum well structure to output the laser beam. As a result, an adjustment of an optical axis is not required, a body of the device can be downsized, and a laser output of the semiconductor laser device, having few noises, can be increased.

Moreover, the semiconductor laser device according to the present invention amplifies and outputs the laser beam of which its wavelength has been selected with the diffraction grating inside the active region. As a result, the distributed feedback semiconductor laser device which is compact, in which an adjustment of an optical axis is not required and a high-power laser beam can be emitted stably can be obtained.

Furthermore, the semiconductor laser device according to the present invention amplifies and outputs the laser beam of which its wavelength has been selected with the diffraction grating provided outside the active region. As a result, the distributed Bragg reflector semiconductor laser device which is compact, in which an adjustment of an optical axis is not required and a high-power laser beam can be emitted stably can be obtained.

Moreover, the semiconductor laser device according to the present invention oscillates the laser beam that includes a plurality of longitudinal modes of oscillation, using the oscillation unit having the normalized coupling coefficient of 2 or more: and amplifies and outputs the laser beam. As a result, a semiconductor laser device which emits a high-power laser beam stably can be obtained.

Furthermore, the semiconductor laser device according to the present invention controls the electric current to be provided to the amplifying unit, to vary the gain of the laser beam. As a result, the semiconductor device which can output a laser beam of a desired power stably can be provided.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor laser device comprising:
an oscillation unit which outputs a laser beam that has a plurality of longitudinal modes of oscillation;
a wavelength converting unit which converts a wavelength of the laser bean that is oscillated by said oscillation unit; and
a light-amplifying unit which amplifies the laser beam that is oscillated by said oscillation unit;
wherein said oscillation unit, said wavelength converting unit, and said light-amplifying unit are placed on the same semiconductor substrate.

2. The semiconductor laser device according to claim 1, wherein said light-amplifying unit has a multiple quantum well structure formed of well layers each having a different thickness or composition.

3. The semiconductor laser device according to claim 1, wherein said oscillation unit comprises a diffraction grating provided inside an active region that pumps the laser beam, and
said oscillation unit is a distributed feedback laser which selects a wavelength of the laser beam with said diffraction grating.

4. The semiconductor laser device according to claim 1, wherein said oscillation unit comprises a diffraction grating provided outside an active region that pumps the laser beam, and
said oscillation unit is a distributed Bragg reflector laser wherein a wavelength selection of the laser beam is done with said diffraction grating.

5. The semiconductor laser device according to claim 1, wherein a normalized coupling coefficient κ×L is equal to or greater than 2, wherein κ is a coupling coefficient and L is a diffraction-grating length of said diffraction grating.

6. The semiconductor laser device according to claim 1, further comprising an electric current control unit that controls an electric current to be supplied to said light-amplifying unit,
wherein said electric current control unit changes an amount of the electric current to be supplied to said light-amplifying unit to change an amount of laser beam output from said light-amplifying unit.
